(19) United States
(12) Patent Application Publication
(10) Pub. No.: US 2010/0241919 A1
(43) Pub. Date: Sep. 23, 2010

(54) METHOD AND APPARATUS FOR ARQ FEEDBACK IN WIRELESS COMMUNICATION SYSTEM

(75) Inventor: Hyung-Joon Jeon, Seongnam-si (KR)

Correspondence Address: AMPACC Law Group, 3500 188th Street S.W., Suite 103, Lynnwood, WA, 98037, US

(73) Assignee: POSDATA CO., LTD., Seongnam-si (KR)

(21) Appl. No.: 12/599,569

(22) PCT Filed: May 9, 2008
(86) PCT No.: PCT/KR2008/002633

§ 371 Date: Nov. 10, 2009

(30) Foreign Application Priority Data
May 10, 2007 (KR) 10-2007-0045706

(51) Int. Cl. H04L 1/18; H04L 1/14; G06F 11/07; G06F 11/10; H03M 13/05

(52) U.S. Cl. 714/750; 714/E11.023; 714/751; 714/E11.032

(57) ABSTRACT

A method and apparatus for Automatic Repeat reQuest (ARQ) feedback in a wireless communication system. The ARQ feedback method includes checking whether feedback transmission on received ARQ blocks with a Cumulative ACK type is possible, and performing ARQ feedback transmission with the Cumulative ACK type when the feedback transmission with the Cumulative ACK type is possible; calculating the number of blocks to be transmitted feedback with a Cumulative ACK with Block Sequence ACK type and the number of blocks to be transmitted feedback with a Cumulative with Selective ACK type, when the feedback transmission with the Cumulative ACK type is not possible; selecting a feedback type by comparing the number of blocks to be transmitted between the Cumulative ACK with Block with Block Sequence ACK type and the Cumulative with Selective ACK type; and performing ARQ feedback with the selected feedback type.

### TECHNICAL FIELD

The present invention relates generally to Automatic Repeat reQuest (ARQ) in a wireless communication system, and in particular, to a method and apparatus for ARQ feedback in a wireless communication system.

### BACKGROUND ART

The Worldwide Interoperability for Microwave Access (WiMAX) wireless Internet standard provides that a receiver uses one of four ARQ feedback types—Selective ACK, Cumulative ACK, Cumulative with Selective ACK, and Cumulative ACK with Block Sequence ACK—in transmitting, to a transmitter, feedback information indicating success/failure in data transmission of the transmitter.

Selective ACK is a scheme for allocating one bit to each block and feeding back to a transmitter the allocated bit indicating success (Acknowledgement (ACK)) or failure (Non-Acknowledgement (NACK)) in data transmission by the transmitter. Cumulative ACK is a scheme for performing feedback on the blocks cumulated up to the successfully received block. Cumulative with Selective ACK is a scheme for performing feedback on the blocks remaining after the Cumulative ACK feedback, using Selective ACK. Cumulative ACK with Block Sequence ACK is a scheme for performing feedback on the blocks remaining after the Cumulative ACK feedback using Cumulative ACK separately for each block sequence.

FIG. 1 illustrates an ARQ window.

Referring to FIG. 1, An ARQ is reset when an ARQ_SYNC_LOSS_TIMEOUT timer expires in an ARQ window of a transmitter. The receiver increases ARQ_RX_WINDOW_START when an ARQ_RX_PURGE_TIMEOUT timer expires in an ARQ window of a receiver.

Further, the corresponding ARQ block is retransmitted, and ARQ_RETRY_COUNT increases its count by 1 when an ARQ_RETRY_TIMEOUT timer expires in the ARQ window of the transmitter. The retransmission continues until ARQ_RETRY_COUNT reaches ARQ_MAX_RETRY_COUNT. The ARQ block is discarded when an ARQ_BLOCK_LIFETIME timer expires in the ARQ window of the transmitter.

Herein, the ARQ_RX_PURGE_TIMEOUT indicates a time interval for which the receiver waits, the ARQ_RETRY_TIMEOUT indicates the minimum waiting time for which the transmitter waits, and the ARQ_BLOCK_LIFETIME indicates the maximum time interval of ARQ blocks managed in the transmitter.

Regarding ARQ feedback duration, it is recommended to send a feedback to a transmitter once before the ARQ_RETRY_TIMEOUT timer for an ARQ block successfully received first after the previous ARQ feedback expires, in order to minimize the network load.

FIG. 2 illustrates a message format of an ARQ_feedback_IE defined in IEEE 802.16e, used for transmitting an ARQ feedback.

Referring to FIG. 2, characteristics of ARQ_feedback_IE are as follows.

Four ACK types—Selective ACK, Cumulative ACK, Cumulative with Selective

ACK, and Cumulative ACK with Block Sequence ACK—are defined by indication of an ‘ACK Type’ field.

The maximum number of ACK Maps available for each ACK type is 4 by indication the ‘Number of ACK Maps’ field, and the ‘Number of ACK Maps’ field is reserved for ACK Type=Cumulative ACK.

In the Cumulative ACK with Block Sequence ACK type, since there are two kinds of block sequence formats, a 2-block sequence format and a 3-block sequence format can be used for feedback on a mixed-use basis. In the Cumulative with Selective ACK type, Selective ACK Map has a 16-bit length and indicates ACK/NACK of an ARQ block. In Cumulative ACK with Block Sequence ACK, the maximum value of ACK/NACK indicated by ACK Map in the 2-block sequence format is (2⁶−1)*2=126, while the maximum value of ACK/NACK indicated by ACK Map in the 3-block sequence format is (2⁴−1)*3=45.

When there is no ARQ block successfully received after the previous ARQ feedback, even though ACK is optional, selecting an available Cumulative ACK type for feedback can reduce a retransmission time, compared with retransmitting each ARQ block based on ARQ_RETRY_TIMEOUT.

When ARQ blocks up to an ARQ block with ARQ_RX_HIGHEST_BSN all have been successfully transmitted, since the smallest (4-byte) feedback header is required and it can indicate all ARQ block states, the receiver selects the Cumulative ACK type for feedback if possible.

In the Cumulative ACK with Block Sequence ACK type, the maximum value of an ARQ block expressible with 16 bits is 126 for the 2-block sequence, while it is 45 for the 3-block sequence. On the other hand, in the Cumulative with Selective ACK type, the maximum number of ARQ blocks expressible by Selective ACK Map is 16.

Therefore, there is a need for an algorithm for performing efficient ARQ feedback to reduce overhead taking into account the characteristic that the maximum number of blocks that can undergo ARQ feedback is different according to the ARQ type.

### DISCLOSURE OF INVENTION

### Technical Problem

An aspect of the present invention is to address at least the problems and/or disadvantages and to provide at least the advantages described below. Accordingly, an aspect of the present invention is to provide a method and apparatus for efficient ARQ feedback in a wireless communication system.

It is another object of the present invention to provide the method and apparatus for reducing in data transmission overhead of the ARQ feedback by performing ARQ feedback through a dynamic selection of ARQ feedback type in the wireless communication system.

### Technical Solution

According to one aspect of the present invention, there is provided a method for Automatic Repeat reQuest (ARQ) feedback in a wireless communication system. The method includes checking whether feedback transmission on received ARQ blocks with a Cumulative ACK type is possible, and performing ARQ feedback transmission with the Cumulative ACK type when the feedback transmission with the Cumulative ACK type is possible; calculating the number of blocks to be transmitted feedback with a Cumulative ACK with Block Sequence ACK type and the number of blocks to be transmitted feedback with a Cumulative with Selective ACK type, when the feedback transmission with the Cumulative ACK type is not possible; selecting a feedback type by comparing the number of blocks to be transmitted between the Cumulative ACK with Block Sequence ACK type and the Cumulative with Selective ACK type; and performing ARQ feedback with the selected feedback type.

According to further another aspect of the present invention, there is provided a method for Automatic Repeat reQuest (ARQ) feedback in a wireless communication system. The method includes determining ACK/NACK based on Cyclic Redundancy Check (CRC) check for each of received ARQ blocks within an ARQ reception window; and selecting an ARQ feedback type based on the number of successive ACKs/NACKs including at least one of ACK/NACK in an ARQ feedback period, and the number of transitions for ACK/NACK.

According to yet another aspect of the present invention, there is provided a method for transmitting feedback information for Automatic Repeat reQuest (ARQ) transmission in a wireless communication system. The method includes managing ARQ reception window status based on determining ACK/NACK by Cyclic Redundancy Check (CRC) check for each of received ARQ blocks within an ARQ reception window; and selecting an ARQ feedback type according to the ARQ reception window status, and performing feedback transmission with the selected ARQ feedback type.

According to another aspect of the present invention, there is provided an apparatus for Automatic Repeat reQuest (ARQ) feedback in a wireless communication system. The apparatus includes a successive ACK/NACK checker for checking successive ACKs/NACKs of received ARQ blocks; a Reception (Rx) window manager for managing an ARQ Rx window using the successive ACKs/NACKs; a Cumulative ACK type determiner for determining to be transmitted feedback with the Cumulative ACK type based on the number of successive ACKs/NACKs including at least one of ACK/NACK; a Cumulative with Selective ACK transmission block calculator for calculating the number of blocks to be transmitted feedback with a Cumulative with Selective ACK type based on the number of successive ACKs/NACKs; and a Cumulative ACK with Block Sequence ACK transmission block calculator for calculating the number of blocks to be transmitted feedback with a Cumulative ACK with Block Sequence ACK type based on the number of successive ACKs/NACKs.

According to further another aspect of the present invention, there is provided an apparatus for Automatic Repeat reQuest (ARQ) feedback in a wireless communication system. The apparatus includes determining means for determining ACK/NACK based on Cyclic Redundancy Check (CRC) check for each of received ARQ blocks within an ARQ reception window; and selecting means for selecting an ARQ feedback type based on the number of successive ACKs/NACKs including at least one of ACK/NACK in an ARQ feedback period, and the number of transitions for ACK/NACK.

### ADVANTAGEOUS EFFECTS

The ARQ feedback method and apparatus according to the present invention selects a proper feedback type according to the ARQ reception window in performing ARQ feedback in the wireless communication system, thereby contributing to a reduction in data transmission overhead of the ARQ feedback.

### BRIEF DESCRIPTION OF THE DRAWINGS

The above and other aspects, features and advantages of the present invention will become more apparent from the following detailed description when taken in conjunction with the accompanying drawings in which:

FIG. 1 illustrates an ARQ window;

FIG. 2 illustrates a message format of an ARQ_feedback_IE defined in IEEE 802.16e, used for transmitting an ARQ feedback;

FIG. 3 illustrates a comparison between Cumulative with Selective ACK and Cumulative ACK with Block Sequences ACK, for various ARQ block states;

FIG. 4 is a flowchart illustrating an ARQ feedback method in a wireless communication system according to the present invention;

FIG. 5 is a flowchart illustrating a window management method for ARQ feedback according to the present invention;

FIGS. 6 to 8 are flowcharts illustrating a detailed example of an ARQ feedback method for obtaining an optimized feedback type in a wireless communication system according to the present invention;

FIGS. 9 and 10 are detailed flowcharts illustrating ARQ window management;

FIG. 11 is a block diagram illustrating a structure of an ARQ feedback apparatus in a wireless communication system according to the present invention; and

FIGS. 12 and 13 are flowcharts illustrating a method for performing Rx window management using a timer.

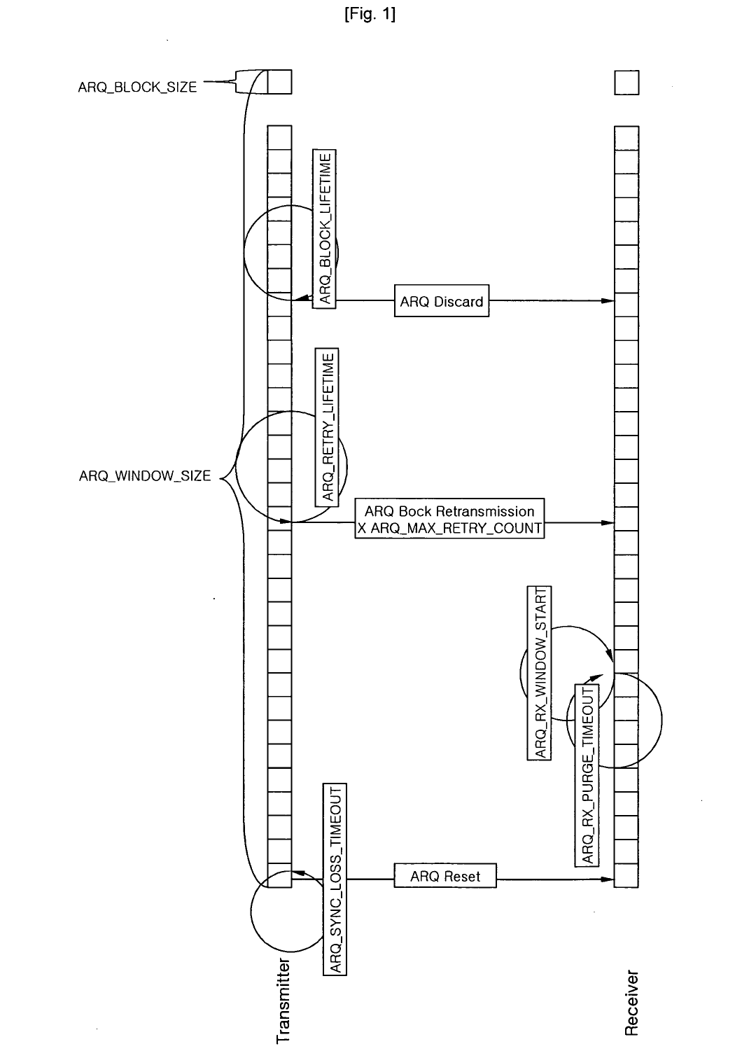

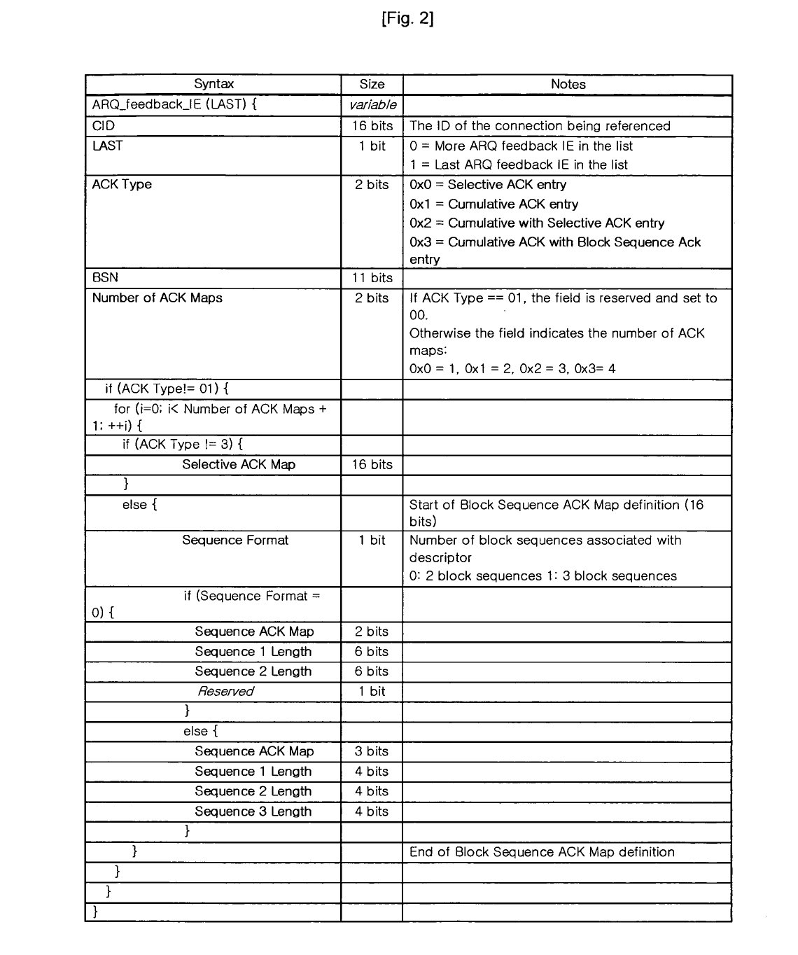

### MODE FOR THE INVENTION

Preferred embodiments of the present invention will now be described in detail with reference to the annexed drawings. In the following description, a detailed description of known functions and configurations incorporated herein has been omitted for clarity and conciseness.

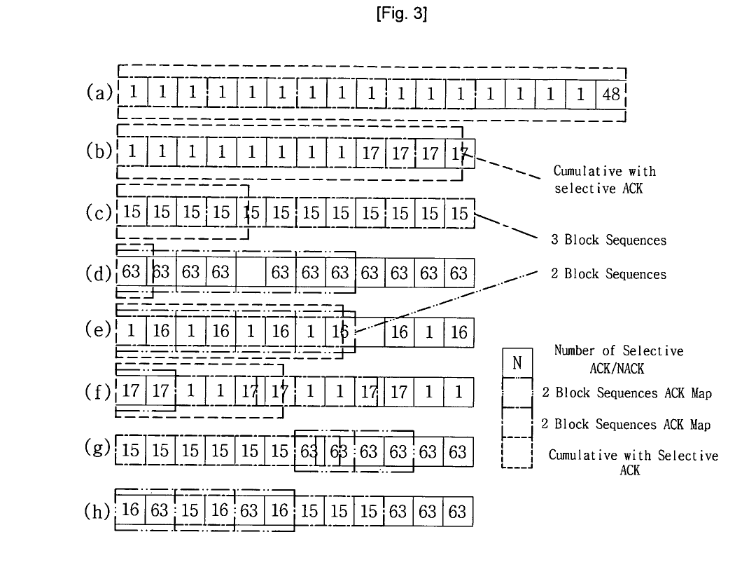

FIG. 3 illustrates a comparison between two ARQ feedback types, i.e., Cumulative with Selective ACK and Cumulative ACK with Block Sequences ACK, for various ARQ block states. Numeral in each box represents the number of successive ACKs/NACKs. In each case shown in FIG. 3, the number of expressible blocks based on the two ARQ feedback types is as follows.

(a) Cumulative with Selective ACK

Cumulative ACK with Block Sequence ACK ((1,1,1), (1,1,1), (1,1,1), (1,1,1)) can express 12 block states, which are less than 64 block states expressible with Cumulative with Selective ACK.

(b) Cumulative with Selective ACK

Cumulative ACK with Block Sequence ACK ((1,1,1), (1,1,1), (1,1,15), (2,15,2)) can express 42 block states, which are less than 64 block states expressible with Cumulative with Selective ACK.

(c) Cumulative with Block Sequence ACK

Cumulative ACK with Block Sequence ACK ((15,15,15), (15,15,15), (15,15,15), (15,15,15)) can express 180 block states, which are greater than 64 block states expressible with Cumulative with Selective ACK.

(d) Cumulative with Block Sequence ACK

Cumulative ACK with Block Sequence ACK ((63,63), (63,63), (63,63), (63,63)) can express 504 block states, which are greater than 64 block states expressible with Cumulative with Selective ACK.

(e) Cumulative with Block Sequence ACK

Cumulative ACK with Block Sequence ACK ((1,16), (1,16), (1,16), (1,16); or (1,15,1), (1,15,1), (1,15,1), (1,15,1)) can express 68 block states, which are greater than 64 block states expressible with Cumulative with Selective ACK.

(f) Cumulative with Block Sequence ACK

Cumulative ACK with Block Sequence ACK ((17,17), (1,1,15), (2,15,2), (1,1,15)) can express 87 block states, which are greater than 64 block states expressible with Cumulative with Selective ACK.

(g) Cumulative with Block Sequence ACK

Cumulative ACK with Block Sequence ACK ((17,15,15), (15,15,15), (63,63), (63,63)) can express 342 block states, which are greater than 64 block states expressible with Cumulative with Selective ACK.

(h) Cumulative with Block Sequence ACK

Cumulative ACK with Block Sequence ACK ((16,63), (15,15,1), (63,16), (15,15,15)) can express 234 block states, which are greater than 64 block states expressible with Cumulative with Selective ACK.

Therefore, the following reasoning is possible. If the number of transitions between ACK and NACK is greater than 12 in 16*4=64 ARQ block states, Cumulative with Selective ACK is suitable. However, if the number of transitions is less than or equal to 8 in 64 ARQ block states, Cumulative ACK with Block Sequence ACK type is suitable.

A description will now be made of the present invention to which the foregoing reasoning is applied.

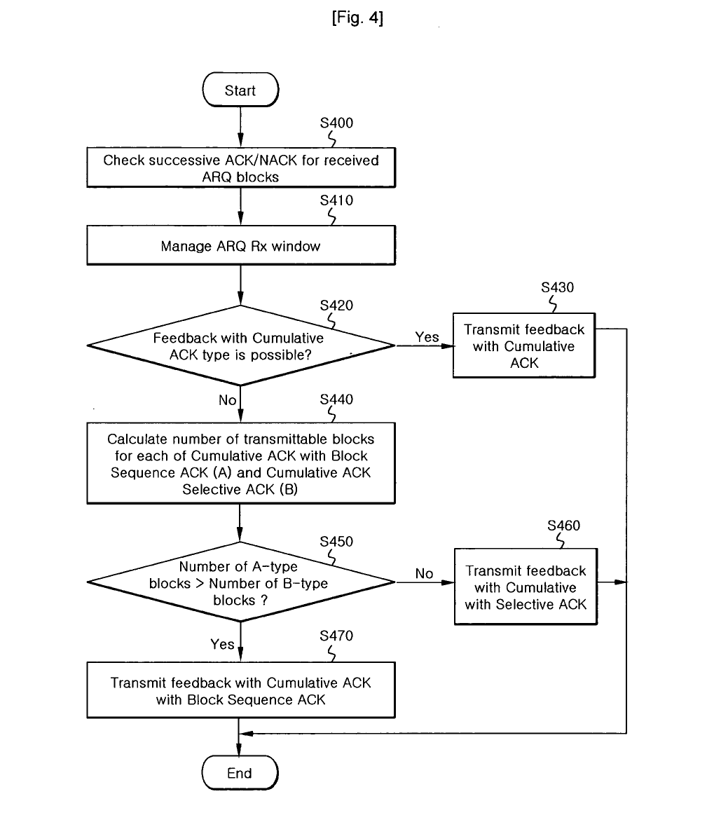

FIG. 4 is a flowchart illustrating an ARQ feedback method of a receiver in a wireless communication system according to the present invention. With reference to FIG. 4, a description will now be made of the present invention.

The receiver performs Cyclic Redundancy Check (CRC) check on received ARQ blocks to check presence of successive ACKs/NACKs in step S400. The receiver manages an ARQ Reception (Rx) window by changing parameters thereof through the CRC check in step S410. Here, management of the ARQ Rx window by the receiver indicates management of an ARQ Rx window status which is determined by the number of transitions of ACK/NACK or the number of successive ACKs/NACKs including at least one ACK/NACK. Thereafter, the receiver checks in step S420 whether feedback with Cumulative ACK is possible, according to whether the CRC check result on the received ARQ blocks within the ARQ Rx window includes only the successive ACKs/NACKs.

If the CRC check result (or ACKs/NACKs) includes only the successive ACKs/NACKs, the receiver performs feedback transmission with the Cumulative ACK type in step S430.

However, if the feedback with the Cumulative ACK type is not possible in step S420, the receiver calculates the number of blocks that can perform feedback transmission with the Cumulative ACK with Block Sequence ACK type, and the number of blocks that can perform feedback transmission with the Cumulative with Selective ACK type in step S440.

The receiver compares in step S450 the calculated numbers of blocks to select the feedback type which is greater in the number of transmittable blocks, and performs ARQ feedback with the selected feedback type. That is, if the number of blocks that can perform feedback transmission with the Cumulative ACK with Block Sequence ACK type is greater than the number of blocks that can perform feedback transmission with the Cumulative with Selective ACK type, the receiver performs feedback transmission with the Cumulative ACK with Block Sequence ACK type in step S470, and otherwise, the receiver performs feedback transmission with the Cumulative with Selective ACK type in step S460.

The ARQ Rx window management in step S410 is performed on the window which includes as many successive ACKs/NACKs array as the number NUM_STATE_CHANGE of transitions of successive ACKs/NACKs. ARQ_Rx_Window_Start indicates a start of the window corresponding to a start of an initial NACK after the successive ACKs in the window. ARQ_RX_HIGHEST_BSN indicates an ARQ block with the highest Block Sequence Number (BSN) among the ARQ blocks received in the window. With use of the ARQ_Rx_Window_Start and ARQ_RX_HIGHEST_BSN, the receiver manages the ARQ Rx window. The ARQ_Rx_Window_Start and ARQ_RX_HIGHEST_BSN of the ARQ Rx window are updated in response to the success in ARQ block reception and/or the expiration of the timer.

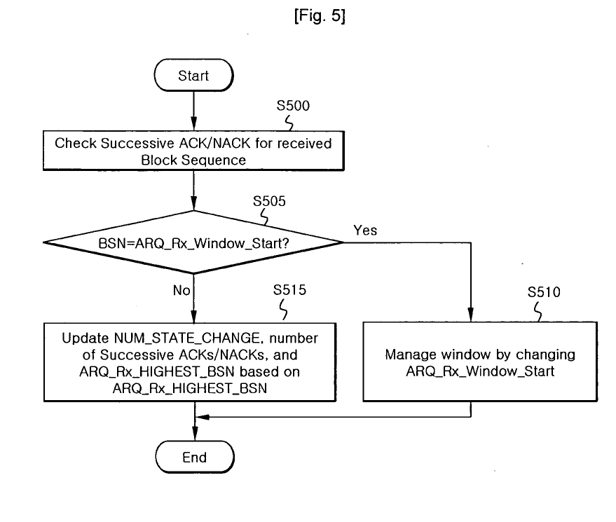

FIG. 5 is a flowchart illustrating a window management method of a receiver for ARQ feedback according to the present invention. The window management method can efficiently determine the ARQ feedback type by checking successive ACKs/NACKs for received block sequences.

Referring to FIG. 5, the receiver performs CRC check on received ARQ blocks to check whether they are successive ACKs/NACKs in step S500. Thereafter, the receiver checks in step S505 whether BSN of the received ARQ blocks is consistent with an ARQ_Rx_Window_Start indicating a start of an initial NACK after successive ACKs in the window. If it is checked that BSN is consistent with ARQ_Rx_Window_Start, the receiver manages the window by changing the ARQ_Rx_Window_Start value according to the number NUM_STATE_CHANGE of transitions from ACK to NACK or from NACK to ACK in step S510.

However, if BSN is inconsistent with ARQ_Rx_Window_Start, the receiver checks whether BSN of the received ARQ block is higher than the highest BSN ARQ_RX_HIGHEST_BSN of ACK in the window, changes the number NUM_STATE_CHANGE of ACK/NACK transitions and ARQ_RX_HIGHEST_BSN for the BSNs higher or lower than ARQ_RX_HIGHEST_BSN, and manages the number of successive ACKs/NACKs for the blocks in step S515.

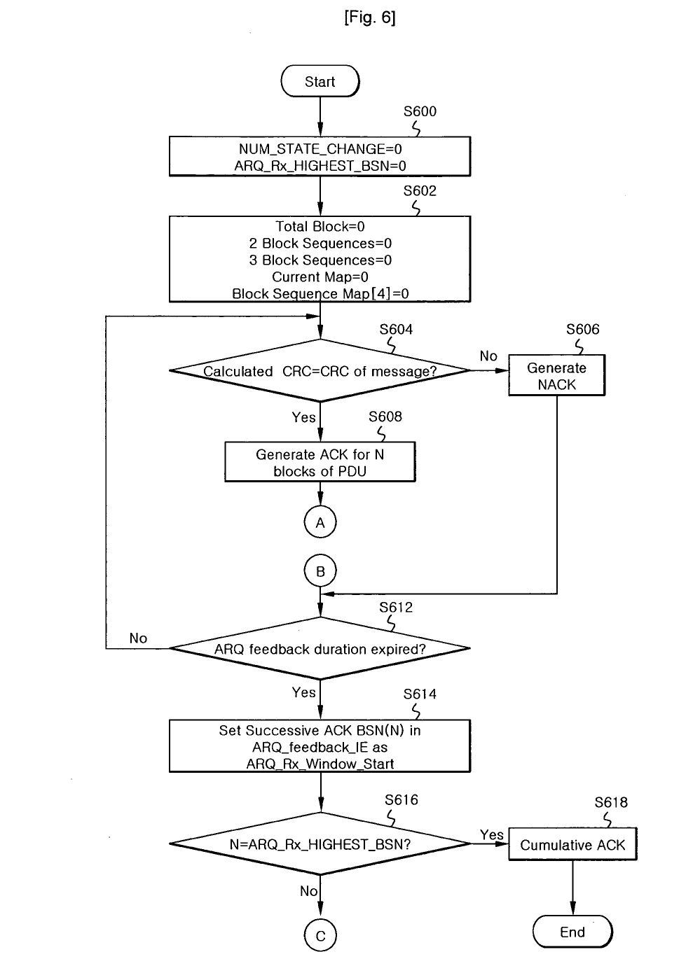

FIGS. 6 to 8 are flowcharts illustrating a detailed example of an ARQ feedback method of a receiver for obtaining the optimized feedback type in a wireless communication system according to the present invention.

Referring to FIGS. 6 to 8, the ARQ feedback method calculates the optimal combination of block sequences for Cumulative ACK with Block Sequence ACK at the expiration of ARQ feedback duration.

The parameters used in FIGS. 6 to 8 are defined as follows. A ‘Total Block’ represents the number of blocks expressible with Cumulative ACK with Block Sequence ACK. A ‘2 Block Sequences’ represents the number of 2-Block Sequences in ARQ feedback. One ARQ feedback ACK Map has 2 bits, and represents two Block Sequences. A ‘3 Block Sequences’ represents the number of 3-Block Sequences in ARQ feedback. One ARQ feedback ACK Map has 3 bits, and represents three Block Sequences. A ‘Current Map’ represents the number of ACK Maps. A ‘Block Sequence Map’ represents an array of Block Sequence ACK Map type [UNDEFINED|TWO|THREE].

In FIGS. 6 to 8, the ARQ feedback method includes roughly divided into 5 steps.

A first step, as an initialization step, initializes variables for ARQ feedback and window management. A second step, as an ARQ Rx window management step, updates an ARQ Rx window associated with a variable such as SUCCESSIVE_ACK_NACK in response to the success in reception of an ARQ block and/or the expiration of a timer. A third step, as a Cumulative ACK step, verifies whether Cumulative ACK is the best feedback mechanism. A fourth step, as a block sequence step, calculates the number of blocks expressible with Cumulative ACK with Block Sequence ACK. A fifth step, as a selection step between Selective and Block Sequence, compares the number of blocks expressible with Cumulative ACK with Block Sequence ACK with the number of blocks expressible with Cumulative and Selective ACK, to select a proper ACK Map type.

With reference to FIGS. 6 to 8, a detailed description of ARQ feedback method will now be given below.

The receiver initializes parameters for ARQ window management in step S600. The parameters include NUM_STATE_CHANGE indicating the number of transitions between ACK and NACK for a block, and ARQ_RX_HIGHEST_BSN indicating an ARQ block with the highest BSN among the ARQ blocks received at the receiver. The variables are initialized to ‘0’.

The receiver initializes other window management variables in step S602. The variables include Total Block, 2 Block Sequences, 3 Block Sequences, Current Map, and Block Sequence Map [4]. The variables are initialized to ‘0’.

The variable ‘Total Block’ represents the number of ARQ blocks expressible with Cumulative ACK with Block Sequence ACK. The variable ‘2 Block Sequences’ represents the number of Block sequences which undergo feedback in the 2-Block Sequence format when the Cumulative ACK with Block Sequence ACK type is used for ARQ feedback. In this case, one ARQ feedback ACK Map includes two Block Sequences. The variable ‘3 Block Sequences’ represents the number of Block Sequences which perform feedback in the 3-Block Sequence format when the Cumulative ACK with Block Sequence ACK type is used for ARQ feedback. In this case, one ARQ feedback ACK Map includes three Block Sequences. The variable ‘Current Map’ represents the number of completed ACK Maps. The variable ‘Block Sequence Map’ represents an array of Block Sequence ACK Map type [UNDEFINED|TWO|THREE] when the Cumulative ACK with Block Sequence ACK type is used.

After completion of the initialization, the receiver manages an ARQ Rx window. To this end, the receiver performs CRC check between calculated CRC and CRC of message on the received ARQ blocks in step S604. If it is checked that CRCs are inconsistent with each other, the receiver generates NACK in step S606, and if CRCs are consistent with each other, the receiver generates ACK for N blocks of Packet Data Unit (PDU) in step S608. After generation of the ACK, the receiver manages an ARQ Rx window for adjusting window variables for which the generated ACK is taken into consideration. A detailed description of the ARQ Rx window will be given below.

When the NACK is generated or when the ARQ Rx window after the ACK generation is managed, the receiver checks in step S612 whether ARQ feedback duration has expired. The ARQ feedback duration can be set as a feedback period defined by the receiver Rx.

If the ARQ feedback duration remains, the receiver checks CRC of a received ARQ block, and if the ARQ feedback duration has expired, the receiver checks whether to perform ARQ feedback using the Cumulative ACK type. More specifically, when successive ACK BSN of the received ARQ blocks are N, the receiver sets N as an ARQ_RX_WINDOW_START value in step S614. Thereafter, the receiver checks in step S616 whether ARQ_RX_WINDOW_START is consistent with ARQ_RX_HIGHEST_BSN.

If ARQ_RX_WINDOW_START is consistent with ARQ_RX_HIGHEST_BSN, the receiver selects the Cumulative ACK type and performs ARQ feedback with the selected Cumulative ACK type in step S618.

However, if ARQ_RX_WINDOW_START is inconsistent with ARQ_RX_HIGHEST_BSN, the receiver determines whether it will use the Cumulative with Selective ACK type or the Cumulative ACK with Block Sequence ACK type. Decision on the two types is made as follows.

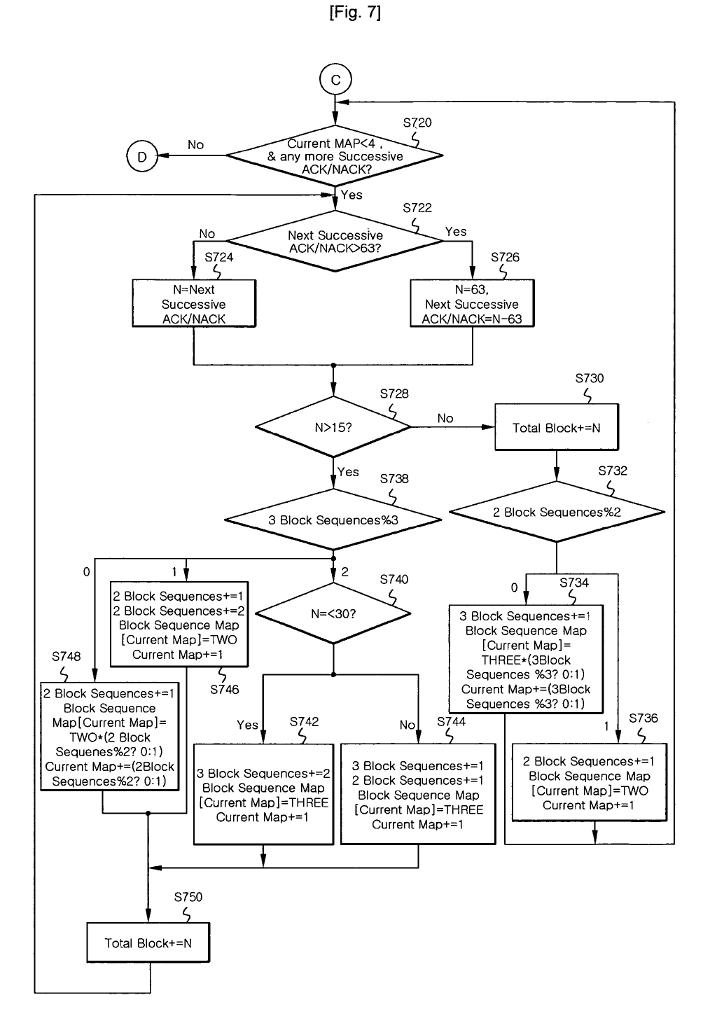

Referring to FIG. 7, the receiver checks in step S720 whether Current Map is less than 4 and there is any remaining successive ACK/NACK to send. If Current Map is less than 4 and there is any remaining successive ACK/NACK to send, the receiver checks in step S722 whether the number of successive ACKs/NACKs is greater than 63, because the maximum value expressible with 6 bits allocated for the 2 Block Sequences is 63. If the number of successive ACKs/NACKs is greater than 63, the receiver sets Successive ACK/NACK to N-63 in step S726, since the maximum number of transmittable ARQ blocks is 63. However, if the number of successive ACKs/NACKs is not greater than 63, the receiver sets N as Successive ACK/NACK in step S724.

Thereafter, the receiver checks in step S728 whether N is greater than 15, which is the maximum value expressible with 4 bits allocated for the 3 Block Sequences. If N is not greater than 15, the corresponding block sequences can be 3 Block Sequence candidates since they can be expressed in the 3-Block Sequence format. Therefore, if N is not greater than 15, the receiver increases Total Block value by N in step S730, and then finds a remainder obtained by dividing a 2 Block Sequence value by 2 in step S732. If the remainder is 0, the receiver increases a 3 Block Sequence value by 1; if the 3 Block Sequence value is divided by 3, the receiver sets Block Sequence Map [Current Map] as THREE; and if the 3-Block Sequence value is not divided by 3, the receiver sets Block Sequence Map [Current Map] as UNDEFINED (THREE*(3 Block Sequences %3 ? 0:1)) in step S734. Further, if the Current Map value is divided by 3, the receiver increases it by (3 Block Sequences %3 ? 0:1).

However, if it is determined in step S732 that the remainder obtained by dividing a 2 block sequence value by 2 is 1, the receiver increases the 2 Block Sequences value by 1, sets a Block Sequence Map [Current Map] value as TWO, and increases Current Map by 1 in step S736.

However, if it is determined in step S728 that N is greater than 15, it means that the corresponding sequences can be 2 Block Sequence candidates. In this case, therefore, the receiver finds a remainder after dividing the 3 Block Sequence value by 3 in step S738. If the remainder found in step S738 is 0, the receiver increases the 2 Block Sequences value by 1; if the 2 Block Sequences value is divided by 2, the receiver sets Block Sequence Map [Current Map] as TWO; and if the 2 Block Sequences value is not divided by 2, the receiver sets Block Sequence Map [Current Map] as UNDEFINED (TWO*(2Block Sequences %2 ? 0:1)) in step S748. In addition, if the 2-Block Sequences value is divided by 2, the receiver increases Current Map by 1, and if the 2 Block Sequences value is not divided by 2, the receiver does not increase Current Map (2Block Sequences %2 ? 0:1).

If it is determined in step S738 that the remainder is 1, the receiver shifts the 3 Block Sequences to 2 Block Sequences. The receiver decreases the 3 Block Sequences value by 1, increases the 2 Block Sequences value by 2, sets Block Sequence Map [Current Map] as TWO, and then increases Current Map by 1 in step S746.

However, if it is determined in step S738 that the remainder is 2, the receiver checks in step S740 whether N is less than or equal to 30. If it is determined in step S740 that N is less than or equal to 30, the receiver divides N by two 3 Block Sequences. Further, the receiver increases the 3 Block Sequences value by 2, sets Block Sequence Map [Current Map] as THREE, and increases Current Map by 1 in step S742.

On the other hand, if N is greater than 30, the receiver allocates 3 Block Sequences for N=15, and 2 Block Sequences for N=N−15. Further, the receiver increases each of the 3 Block Sequences value and 2 Block Sequence value by 1, sets Block Sequence Map [Current Map] as THREE, and increases Current Map by 1 in step S744.

After steps S734, S736, S742, S744, S746 and S748, the receiver increases the Total Block value by N in step S750.

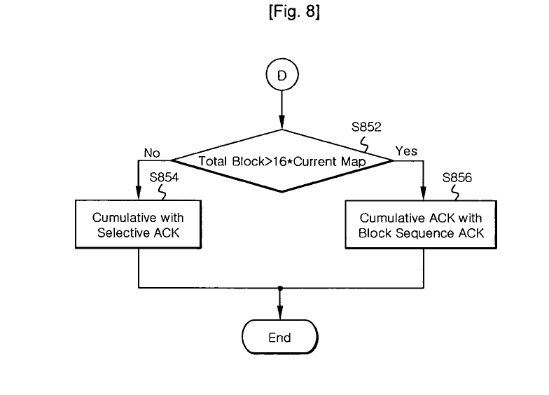

Referring to FIG. 8, if it is determined in step S720 that Current Map is greater than or equal to 4 or there is no more successive ACK/NACK to send, the receiver checks in step S852 whether Total Block is greater than 16*Current Map. Here, 16 is the maximum number of blocks expressible by the Cumulative with Selective ACK type. Therefore, if the maximum number, Total Block, of blocks expressible with block sequences is greater than 16*Current Map, the receiver selects the Cumulative ACK with Block sequence ACK type as it is efficient or suitable, and performs ARQ feedback with the selected Cumulative ACK with Block sequence ACK type in step S856. However, if the Total Block value is less than or equal to 16*Current Map, the receiver selects the Cumulative with Selective ACK type as it is efficient or suitable, and performs ARQ feedback with the selected Cumulative with Selective ACK type in step S854.

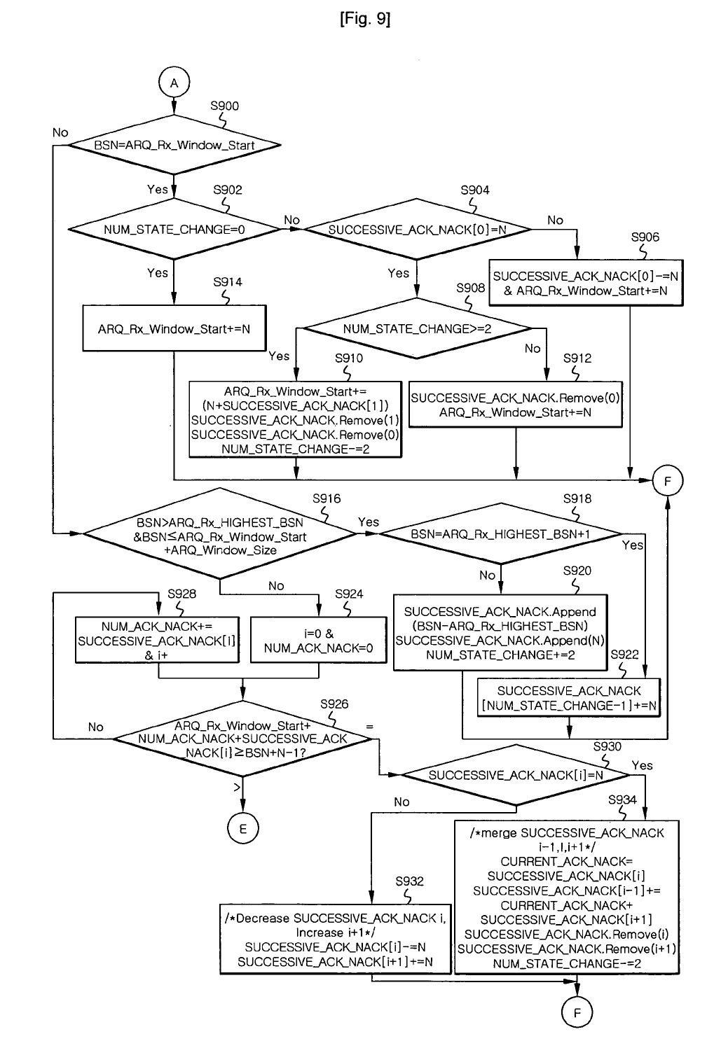

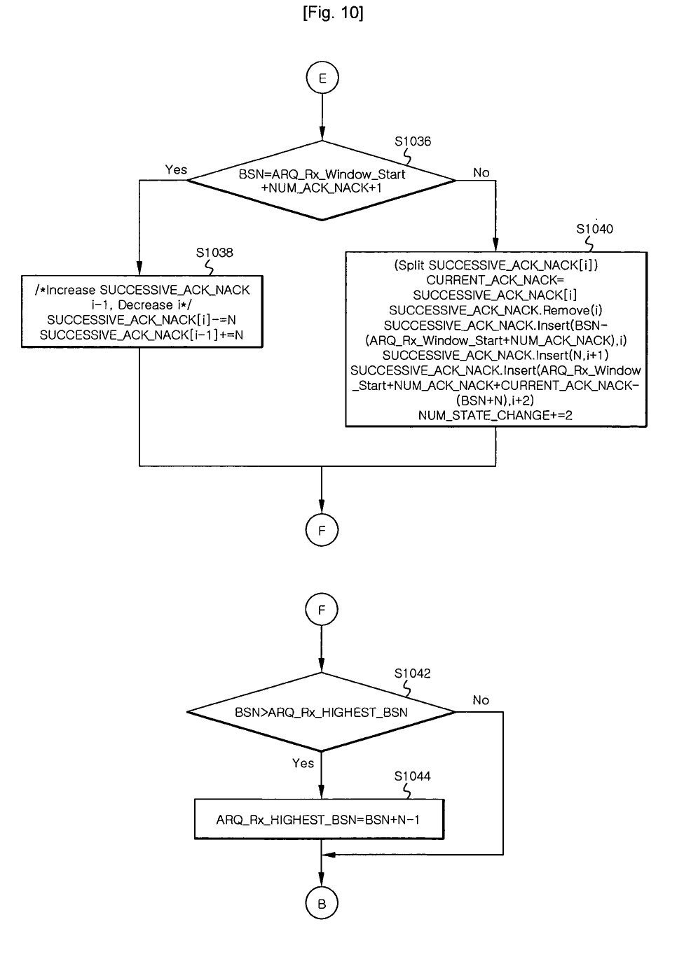

Meanwhile, the ARQ window management of the receiver is achieved as follows. FIGS. 9 and 10 are flowcharts illustrating the ARQ window management after step S608 of FIG. 6. The ARQ window management is a function of managing the ARQ window variables, and specifically, manages successive ACKs/NACKs by making a link list corresponding to the number NUN STATE CHANGE of transitions of ACK/NACK.

Referring to FIGS. 9 and 10, the receiver performs CRC check on a received ARQ block, and if the number of successive ACKs is N (where N is a natural number), the receiver checks in step S900 whether BSN indicating a block sequence number of the received ARQ block is consistent with ARQ_RX_WINDOW_START indicating a window start point. If it is checked that they are consistent with each other, the receiver checks in step S902 whether NUM_STATE_CHANGE is 0. NUM_STATE_CHANGE=0 means that there is no ACK/NACK that underwent ACK/NACK transitions, in the window. If NUM_STATE_CHANGE is 0, the receiver increases only the ARQ_RX_WINDOW_START value by N in step S914.

However, if the NUM_STATE_CHANGE value is not 0, the receiver checks in step S904 whether SUCCESSIVE_ACK_NACK[0] indicating the first array (successive NACK) constituting the window is N. If SUCCESSIVE_ACK_NACK[0] is not N, the receiver decreases the SUCCESSIVE_ACK_NACK[0] value by N, and increases the ARQ_RX_WINDOW_START value by N in step S906.

If it is determined in step S904 that SUCCESSIVE_ACK_NACK[0] is N, the receiver checks in step S908 whether NUM_STATE_CHANGE is greater than or equal to 2. If NUM_STATE_CHANGE is less than 2, i.e., if NUM_STATE_CHANGE is 1, the receiver removes the first element of the window, and increases ARQ_RX_WINDOW_START by N in step S912. If NUM_STATE_CHANGE is greater than or equal to 2, since it means that N successive NACKs, and successive ACKs, the number of which corresponds to a value of SUCCESSIVE_ACK_NACK[1], are included in the window, the receiver increases ARQ_RX_WINDOW_START by (N+SUCCESSIVE_ACK_NACK[1]), performs SUCCESSIVE_ACK_NACK.Remove(0) and SUCCESSIVE_ACK_NACK.Remove(1), and decreases a NUM_STATE_CHANGE value by 2 in step S910.

However, if it is determined in step S900 that BSN is inconsistent with ARQ_RX_WINDOW_START, the receiver checks in step S916 whether BSN is greater than ARQ_RX_HIGHEST_BSN and BSN is less than or equal to ARQ_RX_WINDOW_START+ARQ_WINDOW_SIZE. If this condition is satisfied, the receiver checks in step S918 whether BSN is consistent with ARQ_RX_HIGHEST_BSN+1. This is to check whether the corresponding ACK/NACK is ACK/NACK for BSN just after the highest BSN stored in the window.

If they are consistent with each other, i.e., if the corresponding ACK/NACK is ACK/NACK for BSN just after the highest BSN, the receiver increases a SUCCESSIVE_ACK_NACK [NUM_STAE_CHANGE−1] value by N in step S922. However, if they are inconsistent with each other, i.e., if the corresponding ACK/NACK is not ACK/NACK for BSN just after the highest BSN, the receiver performs SUCCESSIVE_ACK_NACK.Append(BSN-ARQ_RX_HIGHEST_BSN) and SUCCESSIVE_ACK_NACK.Append(N), and increases NUM_STATE_CHANGE by 2 in step S920.

If it is determined in step S916 that BSN is less than ARQ_RX_HIGHEST_BSN, the receiver sets an i and an NUM_ACK_NACK to ‘0’ in step S924, and then checks in step S926 whether ARQ_RX_WINDOW_START+NUM_ACK_NACK+SUCCESSIVE_ACK_NACK[i] is greater than or equal to BSN+N−1. If this condition is not satisfied, the receiver increases NUM_ACK_NACK by SUCCESSIVE_ACK_NAKC[i], and increases the variable i by 1 in step S928.

Thereafter, the receiver goes back to step S926 and repeats the process until ARQ_RX_WINDOW_START+NUM_ACK_NACK+SUCCESSIVE_ACK_NACK[i] is greater than or equal to BSN+N−1.

However, if it is determined in step S926 that ARQ_RX_WINDOW_START+NUM_ACK_NACK+SUCCESSIVE_ACK_NACK[i] is equal to BSN+N−1, the receiver checks in step S930 whether SUCCESSIVE_ACK_NACK[i] is equal to N. If it is checked that they are equal to each other, the receiver merges SUCCESSIVE_ACK_NACK[i−1], SUCCESSIVE_ACK_NACK[i], and SUCCESSIVE_ACK_NACK[i+1] in step S934, reducing the number of transitions by 2. Specifically, the receiver sets CURRENT_ACK_NACK indicating the current number of ACKs/NACKs as SUCCESSIVE_ACK_NACK[i], and increases SUCCESSIVE_ACK_NACK[i-1] by CURRENT_ACK_NACK+SUCCESSIVE_ACK_NACK[i+1]. Further, the receiver removes the i^{th} and (i+1)^{th} elements from the window by performing SUCCESSIVE_ACK_NACK.Remove(i) and SUCCESSIVE_ACK_NACK.Remove (i+1), and decreases NUM_STATE_CHANGE by 2.

However, if it is checked in step S930 that SUCCESSIVE_ACK_NACK[i] is not equal to N, the receiver decreases SUCCESSIVE_ACK_NACK[i] by N, and increases SUCCESSIVE_ACK_NACK[i+1] by N in step S932.

If it is checked in step S926 that ARQ_RX_WINDOW_START+NUM_ACK_NACK+SUCCESSIVE_ACK_NACK[i] is greater than BSN, the receiver checks in step S1036 whether BSN is equal to ARQ_RX_WINDO_STATE+NUM_ACK_NACK+SUCCESSIVE_ACK_NACK[i]+1.

If it is checked that they are equal to each other, the receiver decreases SUCCESSIVE_ACK_NACK[i] by N and increases SUCCESSIVE_ACK_NACK[i-1] by N in step S1038.

However, if it is checked they are unequal to each other, the receiver splits SUCCESSIVE_ACK_NACK[i] in step S1040. That is, the receiver sets CURRENT_ACK_NACK as a SUCCESSIVE_ACK_NACK[i] value, performs SUCCESSIVE_ACK_NACK.Remove(i), performs SUCCESSIVE_ACK_NACK.insert (BSN−(ARQ_RX_WINDOW_START+NUM_ACK_NACK),i)), and performs SUCCESSIVE_ACK_NACK.insert(N, i+1). Further, the receiver performs SUCCESSIVE_ACK_NACK.insert (ARQ_RX_WINDOW_START+NUM_ACK_NACK+CURRENT_ACK_NACK−(BSN+N), i+2), and increases NUM_STATE_CHANGE by 2.

After steps S910, S912, S914, S920, S922, S932, S934, S1038 and S1040, the receiver checks in step S1042 whether the BSN is greater than ARQ_RX_HIGHEST_BSN indicating the highest BSN among the BSNs of the successfully received ARQ blocks. If BSN is greater than ARQ_RX_HIGHEST_BSN, the receiver sets ARQ_RX_HIGHEST_BSN as BSN+N−1 in step S1044, and then returns to step S612 of FIG. 6. However, if BSN is not greater than ARQ_RX_HIGHEST_BSN, the receiver directly processes to step S612. This means that if the received BSN is greater than ARQ_RX_HIGHEST_BSN, the receiver updates ARQ_RX_HIGHEST_BSN.

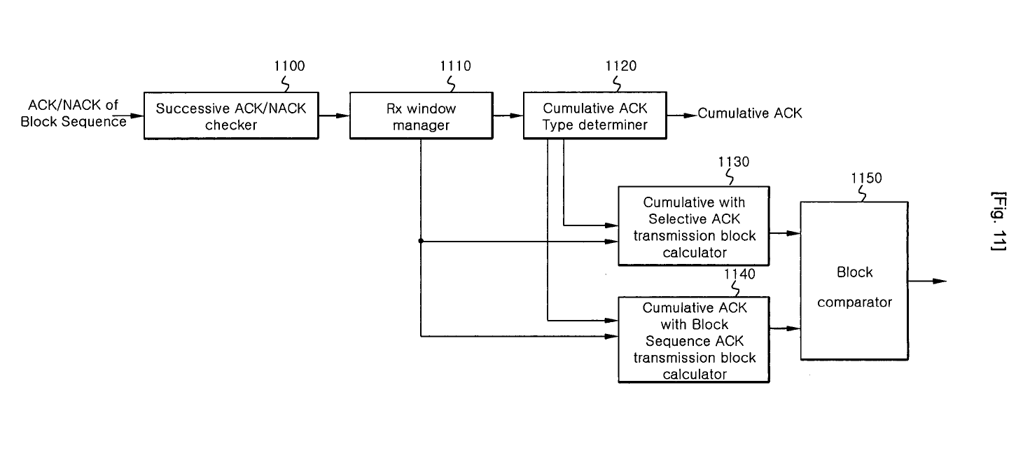

FIG. 11 is a block diagram illustrating a structure of an ARQ feedback apparatus in a wireless communication system according to the present invention.

The ARQ feedback apparatus includes a successive ACK/NACK checker 1100, an Rx window manager 1110, a Cumulative ACK type determiner 1120, a Cumulative with Selective ACK transmission block calculator 1130, a Cumulative ACK with Block Sequence ACK transmission block calculator 1140, and a block comparator 1150.

The successive ACK/NACK checker 1100 checks whether ACK/NACK for a block sequence of the received ARQ blocks is a successive ACK/NACK. The Rx window manager 1110 manages an ARQ Rx window using the successive ACK/NACK checked in the successive ACK/NACK checker 1100. It is preferable to manage the window using a linked list. The Rx window manager 1110 performs the window management using the number NUM_STATE_CHANGE of transitions for ACK/NACK, ARQ_Rx_WINDOW_START indicating the initial NACK position after a successive ACK, ARQ_RX_HIGHEST_BSN indicating the highest BSN, and the number of successive ACKs/NACKs. Here, the window management of the ARQ Rx window indicates management of an ARQ Rx window status which is determined by the number of transitions of ACK/NACK or the number of successive ACKs/NACKs including at least one ACK/NACK.

The Cumulative ACK type determiner 1120 checks whether the successive ACK/NACK stored in the Rx window can be fed back with Cumulative ACK type, and if the successive ACK/NACK can be fed back with Cumulative ACK type, the Cumulative ACK type determiner 1120 determines to perform feedback transmission with the Cumulative ACK type. That is, when only one successive ACK/NACK exists in the window, it is efficient to transmit the feedback with the Cumulative ACK type.

If it is not possible to feed back the successive ACK/NACK stored in the Rx window with the Cumulative ACK type by means of the Cumulative ACK type determiner 1120, the Cumulative with Selective ACK transmission block calculator 1130 calculates the number of blocks that can perform feedback transmission with the Cumulative with Selective ACK type. Similarly, if it is not possible to feed back the successive ACK/NACK stored in the Rx window with the Cumulative ACK type by means of the Cumulative ACK type determiner 1120, the Cumulative ACK with Block Sequence ACK transmission block calculator 1140 also calculates the number of blocks that can undergo feedback transmission with the Cumulative ACK with Block Sequence ACK type.

The block comparator 1150 compares the number of blocks, calculated by the Cumulative with Selective ACK transmission block calculator 1130, with the number of blocks, calculated by the Cumulative ACK with Block Sequence ACK transmission block calculator 1140, to select the feedback type which is greater in the number of transmittable blocks, and performs ARQ feedback with the selected feedback type. That is, if the number of blocks, calculated by the Cumulative with Selective ACK transmission block calculator 1130, is greater than the number of blocks, calculated by the Cumulative ACK with Block Sequence ACK transmission block calculator 1140, the ARQ feedback apparatus performs feedback transmission with the Cumulative with Selective ACK type. Otherwise, the ARQ feedback apparatus performs feedback transmission with the Cumulative ACK with Block Sequence ACK type.

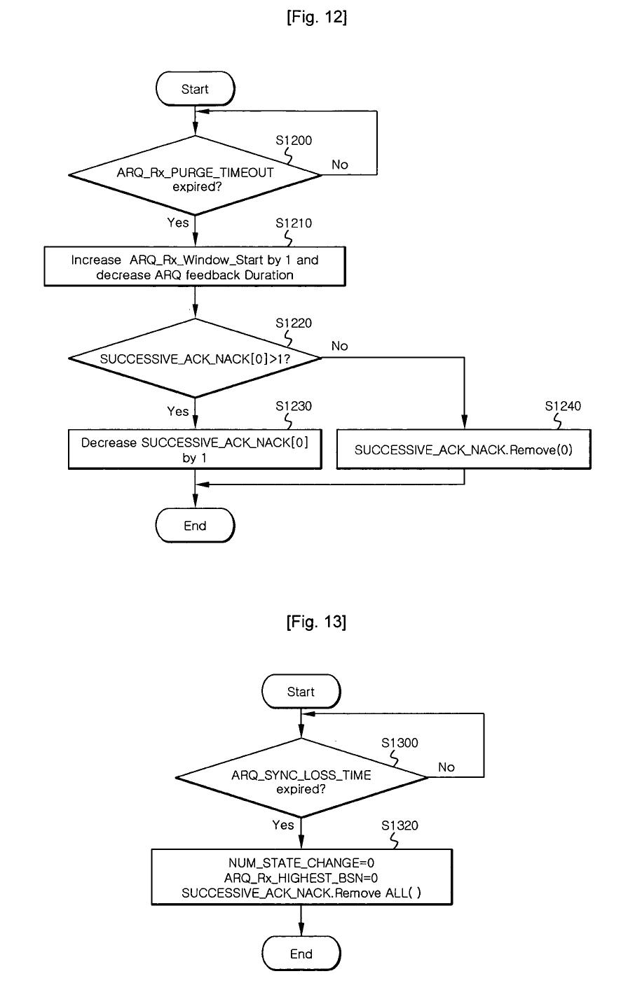

FIGS. 12 and 13 are flowcharts illustrating a method of a receiver for performing Rx window management using a timer.

Referring to FIG. 12, the receiver checks in step S1200 whether ARQ_RX_PURGE_TIMEOUT has expired, in order to remove a block if any, which has not been processed until ARQ_RX_PURGE_TIMEOUT expires. If it is checked that ARQ_RX_PURGE_TIMEOUT has expired, the receiver increases ARQ_RX_WINDOW_START by 1 and decreases ARQ feedback duration in step S1210. In addition, the receiver checks in step S1220 whether SUCCESSIVE_ACK_NACK[0] is greater than 1. If it is determined that SUCCESSIVE_ACK_NACK[0] is greater than 1, the receiver decreases SUCCESSIVE_ACK_NACK[0] by 1 in step S1230, and if SUCCESSIVE_ACK_NACK[0] is not greater than 1, the receiver performs SUCCESSIVE_ACK_NACK.Remove(0) in step S1240. The ARQ_RX_PURGE_TIMEOUT is a time interval for which the receiver waits after successfully receiving a block so that ARQ_RX_WINDOW_START should not advance before its advance.

Referring to FIG. 13, a receiver checks in step S1300 whether ARQ_SYNC_LOSS_TIMEOUT has expired. If ARQ_SYNC_LOSS_TIMEOUT has expired, the receiver sets NUM_STATE_CHANGE to ‘0’, sets even ARQ_RX_HIGHEST_BSN to ‘0’, and performs SUCCESSIVE_ACK_NACK. Remove All( ) in step S1320. The ARQ_SYNC_LOSS_TIMEOUT is the maximum time interval for allowing ARQ_RX_WINDOW_START to remain at the same value before the transmitter and receiver declare a synchronization loss when it is recognized that the data transmission is in the active state.

Meanwhile, functions used in an apparatus and a method disclosed in the present specification can be embodied in storage media that a computer can read as codes that the computer can read. The storage media that the computer can read, include all sorts of record devices in which data that can be read by a computer system is stored. Examples of the storage media that the computer can read, include ROMs, RAMs, CDROMs, magnetic tape, floppy discs, optic data storage devices, etc., and also, include things embodied in the form of carrier wave (e.g., transmission through the internet). Furthermore, the storage media that the computer can read is distributed in a computer system connected with networks. Then, the codes that the computer can read, are stored in the distributed storage media in a distribution scheme, and the codes can be executed in the distribution scheme.

While the invention has been shown and described with reference to a certain preferred embodiment thereof, it will be understood by those skilled in the art that various changes in form and details may be made therein without departing from the spirit and scope of the invention as defined by the appended claims.

1. A method for Automatic Repeat reQuest (ARQ) feedback in a wireless communication system, the method comprising:
checking whether feedback transmission on received ARQ blocks with a Cumulative ACK type is possible, and performing ARQ feedback transmission with the Cumulative ACK type when the feedback transmission with the Cumulative ACK type is possible;
calculating the number of blocks to be transmitted feedback with a Cumulative ACK with Block Sequence ACK type and the number of blocks to be transmitted feedback with a Cumulative with Selective ACK type, when the feedback transmission with the Cumulative ACK type is not possible;
selecting a feedback type by comparing the number of blocks to be transmitted between the Cumulative ACK with Block Sequence ACK type and the Cumulative with Selective ACK type; and
performing ARQ feedback with the selected feedback type.

2. The method of claim 1, wherein the step of checking further comprises:
checking successive ACKs/NACKs for the received ARQ blocks, and managing an ARQ Reception (Rx) window using variables of the ARQ Rx window.

3. The method of claim 2, wherein the ARQ Rx window includes successive ACKs/NACKs array as the number NUM_STATE_CHANGE of transitions of the successive ACKs/NACKs.

4. The method of claim 2, wherein the variables of the ARQ Rx window include a ARQ_Rx_Window_Start indicating a start of an initial NACK after a successive ACK in the ARQ Rx window, a ARQ_RX_HIGHEST_BSN indicating a highest block sequence number of an ACK in the ARQ Rx window, and a NUM_STATE_CHANGE indicating the number of successive ACK/NACK transitions.

5. The method of claim 2, wherein the step of managing the ARQ Rx window comprises:
changing a window start variable ARQ_Rx_Window_Start and ARQ feedback duration in response to success in reception of the received ARQ blocks or expiration of a timer.

6. The method of claim 2, wherein the step of managing the ARQ Rx window comprises:
checking whether ACK/NACK for a received block sequence of the received ARQ blocks is successive; and checking whether a Block Sequence Number (BSN) of the received ARQ blocks is consistent with a ARQ_Rx_Window_Start indicating a start point of a NACK after successive ACKs, and managing the window by changing the ARQ_Rx_Window_Start depending on the number of transitions for ACK/NACK when the BSN is consistent with the variable ARQ_Rx_Window_Start.

7. The method of claim 6, wherein the step of managing the ARQ Rx window comprises:
checking whether the received BSN is greater than a highest BSN ARQ_RX_HIGHEST_BSN of an ACK in the window when the BSN is inconsistent with ARQ_Rx_Window_Start, and managing the number of ACK/NACK transitions and the number of successive ACKs/NACKs.

8. An apparatus for Automatic Repeat reQuest (ARQ) feedback in a wireless communication system, the apparatus comprising:
a ACK/NACK checker for checking successive ACKs/NACKs of received ARQ blocks;
a window manager for managing an ARQ Rx window using the successive ACKs/NACKs;
a Cumulative ACK type determiner for determining feedback transmission with a Cumulative ACK type based on the number of successive ACKs/NACKs including at least one of ACK/NACK;
a first transmission block calculator for calculating the number of blocks to be transmitted feedback with a Cumulative with Selective ACK type based on the number of successive ACKs/NACKs;
a second transmission block calculator for calculating the number of blocks to be transmitted feedback with a Cumulative ACK with Block Sequence ACK type based on the number of successive ACKs/NACKs; and
a comparator for comparing the number of blocks to be transmitted feedback with a Cumulative ACK with Block Sequence ACK type with the number of blocks to be transmitted feedback with a Cumulative with Selective ACK type to select a feedback type.

9. A method for Automatic Repeat reQuest (ARQ) feedback in a wireless communication system, the method comprising:
determining ACK/NACK based on Cyclic Redundancy Check (CRC) check for each of received ARQ blocks within an ARQ reception window; and
selecting an ARQ feedback type based on the number of successive ACKs/NACKs including at least one of ACK/NACK in an ARQ feedback period, and the number of transitions for ACK/NACK.

10. The method of claim 9, wherein the ARQ feedback type is at least one of a Cumulative ACK feedback type, a Cumulative with Selective ACK feedback type, and a Cumulative ACK with Block Sequence ACK feedback type.

11. The method of claim 10, wherein the Cumulative ACK with Block Sequence ACK feedback type comprises a format of a 2-block sequence or a 3-block sequence.

12. A method for transmitting feedback information for Automatic Repeat reQuest (ARQ) transmission in a wireless communication system, the method comprising:
managing ARQ reception window status based on determining ACK/NACK by Cyclic Redundancy Check (CRC) check for each of received ARQ blocks within an ARQ reception window; and
selecting an ARQ feedback type according to the ARQ reception window status, and performing feedback transmission with the selected ARQ feedback type.

13. The method of claim 9, wherein the ARQ feedback type is at least one of a Selective ACK feedback type, a Cumulative ACK feedback type, a Cumulative with Selective ACK feedback type and a Cumulative ACK with Block Sequence ACK feedback type.

14. The method of claim 13, wherein the ARQ reception window status is determined by the number of ACK/NACK transitions.

15. The method of claim 13, wherein the ARQ reception window status is determined by the number of successive ACKs/NACKs including at least one ACK/NACK.

16. The method of claim 14, wherein the Cumulative ACK with Block Sequence ACK feedback type is selected, when the number of transitions for the number 64 of the received ARQ blocks is less than or equal to 8.

17. The method of claim 14, wherein the Cumulative with Selective ACK feedback type is selected, when the number of transitions for the number 64 of the received ARQ blocks is greater than or equal to 12.

18. (canceled)
